(19) United States
(12) Patent Application Publication
(10) Pub. No.: US 2004/0259365 A1
(43) Pub. Date: Dec. 23, 2004

(54) Polishing method polishing system and method for fabricating semiconductor device

(76) Inventors: Naoki Komai, Kanagawa (JP); Takeshi Nogami, Kanagawa (JP); Shingo Takahashi, Kanagawa (JP); Hiroshi Horikoshi, Kanagawa (JP); Kaori Tai, Kanagawa (JP); Shuzo Sato, Kanagawa (JP); Hiizu Ohtorii, Kanagawa (JP)

Correspondence Address: ROBERT J. DEPKE LEWIS T. STEADMAN, HOLLAND & KNIGHT LLC, 131 SOUTH DEARBORN, 30TH FLOOR, CHICAGO, IL, 60603, US

(21) Appl. No.: 10/484,013

(22) PCT Filed: May 20, 2003
(86) PCT No.: PCT/JP03/06280

(30) Foreign Application Priority Data
May 21, 2002 (JP) 2002-146117

(51) Int. Cl. H01L 21/302; H01L 21/461

(52) U.S. Cl. 438/691

(57) ABSTRACT

There are provided a polishing method and a polishing apparatus for appropriately controlling the potential of an acting electrode to perform an accurate and stable electrolytic polishing process. There is also provided a method of manufacturing a semiconductor device using the polishing method and the polishing apparatus. In the polishing method according to the present invention, a substrate with a metal film formed thereon and a counter electrode are disposed in facing relation to each other in an electrolytic liquid, and a current is supplied to the metal film through the electrolytic liquid based on the potential of the metal film with respect to a reference electrode. The polishing apparatus according to the present invention has, disposed in an electrolytic liquid, a substrate with a metal film formed thereon, a counter electrode disposed in facing relation to the substrate with a predetermined gap therebetween, and a reference electrode for providing a reference potential for the metal film, wherein a current is supplied to the metal film through the electrolytic liquid based on the potential of the metal film with respect to the reference electrode.

### TECHNICAL FIELD

The present invention relates to a polishing method, a polishing apparatus, and a method of manufacturing a semiconductor device.

### BACKGROUND ART

In the semiconductor device fabrication process, surface planarization is required due to limitations posed on DOF (depth of focus) on exposed surfaces by the trend toward finer patterns on semiconductor devices. For such surface planarization, CMP (Chemical Mechanical Polishing) processes have already been widely used in general. There has been a process, typified by a damascene process developed by IBM, by which a metal film is embedded in recesses and excessive metal deposited on a surface layer is removed by the CMP process, forming wirings and vias in the recesses.

From the standpoint of materials, copper wirings have been developed at an accelerated pace after they were introduced by IBM in 1997 for the purpose of reducing wiring delays which had increased to a non-negligible level among operation delays due to finer patterns. The use of copper wirings has been accelerated from about a 0.1 μm node, and conductive metal materials for use in forming wirings have been changing from aluminum, which has heretofore been used, to copper of lower electric resistance. For a next 0.07 μm node, since wiring delays are greater than device transistor delays in operation delays on a combination of silicon-oxide insulating films and copper wirings, it is essential to further reduce the dielectric constant of an wiring structure employed so far, particularly insulting films.

Various films of low dielectric constants have been developed in view of the above background. However, any of those developed films are made of materials having low mechanical strength, such as porous materials, and hence cannot withstand the conventional CMP process which poses a high pressure. It has been proposed to employ the electrolytic polishing process for forming wirings under a pressure lower than the CMP process.

The electrolytic polishing process has been used over a long period of time for polishing metal surfaces. In recent years, the electrolytic polishing process has also been used as a technique for polishing industrial products. According to the electrolytic polishing process, a workpiece to be polished is immersed in a special electrolytic liquid, and is polished by electrolysis. Usually, the electrolytic polishing process employs two electrodes as with the plating process. The electrolytic polishing process may be carried out by a polishing apparatus 401 shown in FIG. 14 of the accompanying drawings. The polishing apparatus 401 has an electrolytic tank 402 holding an electrolytic liquid E therein, with a wafer W and a counter electrode 403 disposed in the electrolytic tank 402 and immersed in the electrolytic liquid E in confronting relation to each other. Electrodes are directly connected to the wafer W, which functions as acting electrodes (anode) 404. A DC power supply 405 is connected to the acting electrode 404 and the counter electrode 403 for applying a voltage between the acting electrode 404 and the counter electrode 403. A voltage detecting circuit 406 is connected between the acting electrode 404 and the counter electrode 403, and a control device 407 for controlling the applied voltage and a function generator 408 for controlling the waveform of the voltage are connected to the DC power supply 405.

Since very small surface irregularities are planarized in the wafer process, it is necessary to manage a small polishing quantity in the wafer process. In the electrolytic polishing process, an oxidizing reaction occurs on the anode which is the acting electrode and a reductive reaction occurs on the cathode which is the counter electrode, and the applied voltage represents a total voltage as the potential difference between the electrodes. In the wafer process based on the electrolytic polishing process, the important potential is the potential of the anode, and it is necessary to control the potential of the anode in order to control the electrochemical reaction on the anode in the electrolytic polishing process.

When hydrogen is generated at the cathode upon electrolysis, bubbles of hydrogen change the electrode area of the cathode, and the change in the effective area of the electrode results in a change in the electrode resistance of the cathode. Furthermore, the interfacial resistance of the cathode increases due to the effect of by-products. In the electrolytic polishing process, it is the general practice to perform electrolysis under constant-voltage control for the purpose of controlling the interfacial reaction upon electrolysis. If the interfacial resistance and the electrode resistance of the cathode change, then the resistance value of a portion of the circuit during the electrolytic polishing process changes, resulting in a change in the potential of the anode which needs to be controlled. Since it is difficult to keep the potential of the anode electrode constant, the electrochemical reaction in question cannot be controlled. That is, it is not possible to manage and control a small polishing quantity for accurate polishing.

The present invention has been made in view of the conventional situation described above. It is an object of the present invention to provide a polishing method and a polishing apparatus for appropriately controlling the potential of an acting electrode to perform an accurate and stable electrolytic polishing process.

### DISCLOSURE OF INVENTION

A polishing method according to the present invention for achieving the above object is characterized in that a substrate with a metal film formed thereon and a counter electrode are disposed in facing relation to each other in an electrolytic liquid, and a current is supplied to the metal film through the electrolytic liquid based on the potential of the metal film with respect to a reference electrode.

A polishing apparatus according to the present invention for achieving the above object comprises a substrate with a metal film formed thereon, a counter electrode disposed in facing relation to the substrate with a predetermined gap therebetween, and a reference electrode for providing a reference potential for the metal film, the substrate, the counter electrode, and the reference electrode being disposed in an electrolytic liquid, wherein a current is supplied to the metal film through the electrolytic liquid based on the potential of the metal film with respect to the reference electrode.

The polishing method and the polishing apparatus according to the present invention employ a three-electrode process using the reference electrode, and it is possible to accurately measure the potential of the metal film during a polishing process using the potential of the reference electrode as a reference. Thus, the potential of the metal film serving as an anode can be controlled at a predetermined potential from the start of the polishing process to the end of the polishing process, making it possible to control the electrochemical reaction on the metal film at a desired state. Even when the resistance value of a portion of the circuit is changed by a change in the interfacial resistance or the electrode resistance of the cathode or a change in the resistance value of the electrolytic liquid during the polishing process, resulting in a change in the polishing environment, the potential of the metal film serving as the anode can be controlled adequately, thus controlling the electrochemical reaction on the metal film at a desired state. The electrolytic polishing process can be controlled in submicron levels, and hence the electrolytic polishing process can be performed accurately and stably.

A method of manufacturing a semiconductor device according to the present invention has the steps of forming an wiring groove in an insulating film on a substrate to form a metal wiring thereon, forming a metal film on the insulating film so as to fill the wiring groove, and polishing the metal film on the insulating film, characterized in that in the step of polishing the metal film, the substrate with the metal film formed thereon and a counter electrode are disposed in facing relation to each other in an electrolytic liquid, and a current is supplied to the metal film through the electrolytic liquid based on the potential of the metal film with respect to a reference electrode.

With the method of manufacturing a semiconductor device according to the present invention, since the polishing method which has good and stable processing accuracy as described above is carried out to planarize the surface at the time the metal wiring is formed, the surface of the metal wiring can highly be planarized without causing defects or the like after the metal wiring is planarized.

### BRIEF DESCRIPTION OF DRAWINGS

FIG. 1 is a schematic view showing an arrangement of a polishing apparatus to which the present invention is applied;

FIG. 2 is a schematic view showing another arrangement of a polishing apparatus to which the present invention is applied;

FIG. 3 is a schematic view showing another arrangement of a polishing apparatus to which the present invention is applied;

FIG. 4 is a plan view illustrative of the manner in which a polishing pad of the polishing apparatus and a wafer slide against each other;

FIG. 5 is a cross-sectional view taken along line A-A′ of FIG. 4;

FIG. 6 is an enlarged cross-sectional view of an encircled area B in FIG. 5;

FIG. 7 is an enlarged plan view of an encircled area C in FIG. 4;

FIG. 8 is a schematic view showing another arrangement of a polishing apparatus to which the present invention is applied;

FIG. 9 is a view illustrative of a method of manufacturing a semiconductor device according to the present invention, the view being a fragmentary cross-sectional view showing a state in which an interlayer insulating film is formed;

FIG. 10 is a view illustrative of the method of manufacturing a semiconductor device according to the present invention, the view being a fragmentary cross-sectional view showing a state in which wiring grooves and contact holes are formed;

FIG. 11 is a view illustrative of the method of manufacturing a semiconductor device according to the present invention, the view being a fragmentary cross-sectional view showing a state in which a barrier film is formed;

FIG. 12 is a view illustrative of the method of manufacturing a semiconductor device according to the present invention, the view being a fragmentary cross-sectional view showing a state in which a seed film is formed;

FIG. 13 is a view illustrative of the method of manufacturing a semiconductor device according to the present invention, the view being a fragmentary cross-sectional view showing a state in which a Cu film is formed; and

FIG. 14 is a schematic view showing an arrangement of a conventional two-electrode polishing apparatus.

### BEST MODE FOR CARRYING OUT THE INVENTION

A polishing method, a polishing apparatus, and a method of manufacturing a semiconductor device according to the present invention will be described in detail below with reference to the drawings. In the drawings described below, the scales may be different from actual dimensions for an easier understanding of the present invention. The present invention is not limited to the description which follows, and suitable changes may be made therein without departing from the scope of the present invention.

In a polishing method according to the present invention, a substrate with a metal film formed thereon and a counter electrode are disposed in facing relation to each other in an electrolytic liquid, and a current is supplied to the metal film through the electrolytic liquid based on the potential of the metal film with respect to a reference electrode.

A polishing apparatus according to the present invention has, disposed in an electrolytic liquid, a substrate with a metal film formed thereon, a counter electrode disposed in facing relation to the substrate with a predetermined gap therebetween, and a reference electrode for providing a reference potential for the metal film, wherein a current is supplied to the metal film through the electrolytic liquid based on the potential of the metal film with respect to the reference electrode.

A method of manufacturing a semiconductor device according to the present invention has the steps of forming an wiring groove in an insulating film on a substrate to form a metal wiring thereon, forming a metal film on the insulating film so as to fill the wiring groove, and polishing the metal film on the insulating film, wherein in the step of polishing the metal film, the substrate with the metal film formed thereon and a counter electrode are disposed in facing relation to each other in an electrolytic liquid, and a current is supplied to the metal film through the electrolytic liquid based on the potential of the metal film with respect to a reference electrode.

The present invention will be described below as being applied to the planarization of a Cu wiring in a semiconductor wiring forming process, i.e., where the metal film formed on a wafer as the substrate is a Cu film.

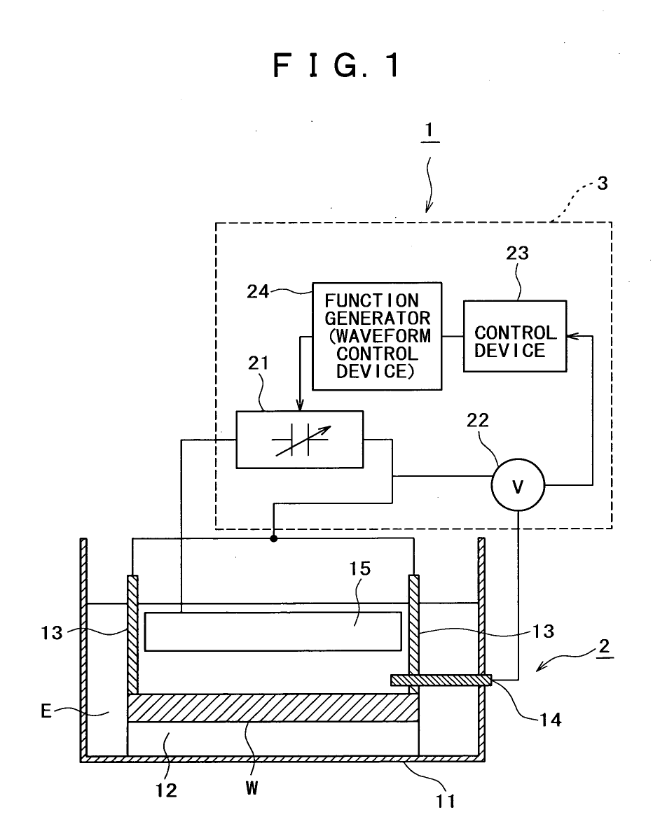

The polishing apparatus according to the present invention will first be described below. FIG. 1 is a schematic view showing an arrangement of a polishing apparatus 1 to which the present invention is applied. The polishing apparatus 1 is an apparatus for planarizing, by way of an electrolytic action, a Cu film which is formed on a substrate as an object to be polished and serves as an anode to which a current is supplied. The polishing method according to the present invention is not limited to a polishing method which uses the polishing apparatus to be described below, but is applicable to various polishing methods.

The polishing apparatus 1 comprises an apparatus assembly 2 for polishing a wafer W and a potentiostat 3 for controlling and supplying a predetermined electrolytic current to the apparatus assembly 2.

The apparatus assembly 2 has an electrolytic tank 11 for storing an electrolytic liquid E therein and placing the wafer W and other parts therein, and a wafer chuck 12 for securing the wafer W that is immersed in the electrolytic liquid E in the electrolytic tank 11, with the surface of the wafer W on which a Cu film is formed facing upwardly. An electrode is directly connected to the wafer W with the Cu film form thereon, and functions as an acting electrode (anode) 13. A reference electrode 14 comprising a calomel electrode is disposed highly closely to the acting electrode 13, so that a voltage between the acting electrode 13 and the reference electrode 14 can be measured upon electrolysis.

In the electrolytic tank 11, a counter electrode (cathode) 15 which is substantially disk-shaped and immersed in the electrolytic liquid E is disposed above the wafer W in facing relation thereto by a counter electrode holding member (not shown). The wafer W and the counter electrode 15 are disposed in facing relation to each other with the electrolytic liquid E interposed therebetween. The counter electrode 15 is made of an electrode material such as Cu, Pt.

The potentiostat 3 controls a current flowing between the acting electrode 13 and the reference electrode 14 to equalize the voltage between the acting electrode 13 and the reference electrode 14 to a preset value. The potentiostat 3 comprises a power supply 21 connected to the acting electrode 13 and the reference electrode 14, a voltage detecting circuit 22 positioned between the acting electrode 13 and the reference electrode 14 for detecting a voltage therebetween, a control device 23 for analyzing a circuit signal from the voltage detecting circuit 22 to control the output voltage of the power supply 21, and a function generator 24 for controlling a waveform based on a control command signal sent from the control device 23 to control a process of applying a voltage from the power supply 21.

Since the polishing apparatus 1 thus constructed is of the three-electrode type using the reference electrode 14, it is possible to accurately measure the potential of the acting electrode 13, i.e., the potential of the Cu film, rather than the voltage applied to the electrolytic circuit, by measuring the voltage between the acting electrode 13 and the reference electrode 14 with the voltage detecting circuit 22 and using the potential of the reference electrode 14 as a reference during an electrolytic polishing process. The detected result from the voltage detecting circuit 22 is analyzed by the control device 23. Based on the analyzed result, the power supply 21 controls the voltage applied between acting electrode 13 and the reference electrode 14. In this manner, the potential of the Cu film can be controlled at a predetermined potential from the start of the polishing process to the end of the polishing process.

As a consequence, even when the resistance value of a portion of the circuit is changed by a change in the interfacial resistance or the electrode resistance of the counter electrode serving as the cathode or a change in the resistance value of the electrolytic liquid E during the polishing process, resulting in a change in the polishing environment, the potential of the Cu film serving as the anode can be controlled adequately, thus controlling the electrochemical reaction, i.e., the dissolving reaction, on the Cu film at a desired state. The Cu film formed on the wafer W can thus be polished accurately and reliably. Therefore, the polishing apparatus 1 is capable of controlling the electrolytic polishing process in submicron levels, and hence of performing the electrolytic polishing process accurately and stably.

A polishing process for polishing the Cu film on the wafer W with the polishing apparatus 1 will be described below.

The wafer W to be polished is fixed to the wafer chuck 12 and placed in the electrolytic tank 11 filled with the electrolytic liquid E, with the surface of the wafer W on which the Cu film is formed facing upwardly. The counter electrode (cathode) 15 is fixed by the counter electrode holding member (not shown) and immersed in the electrolytic liquid E at a position above the wafer W in facing relation thereto. The reference electrode 14 comprising a calomel electrode is disposed highly closely to the wafer W. An electrolytic voltage is applied through the electrolytic liquid E between the wafer W, which serves as an acting electrode (anode), and the counter electrode 15 to pass an electrolytic current, thus supplying a current to the Cu film. The Cu film on the acting electrode causes an oxidizing reaction, dissolving copper in the Cu film, which is polished and planarized.

At this time, the voltage between the acting electrode 13 and the reference electrode 14 is detected by the voltage detecting circuit 22. The detected result is analyzed by the control device 23, and the power supply 21 controls the voltage applied between the acting electrode 13 and the reference electrode 14 so as to cause a desired electrochemical reaction on the Cu film on the acting electrode based on the analyzed result. That is, the potential of the Cu film is controlled at a predetermined potential for bringing about a desired electrochemical reaction from the start of the polishing process to the end of the polishing process. The function generator 24 controls a process of applying a power supply such as a direct current, a pulse, a triangle wave, a step wave, a ramp wave, etc. to apply a voltage having an optimum waveform.

In this manner, even when the resistance value of a portion of the circuit is changed by a change in the interfacial resistance or the electrode resistance of the counter electrode serving as the cathode or a change in the resistance value of the electrolytic liquid E, resulting in a change in the polishing environment, the potential of the metal film serving as the anode can be controlled adequately, thus controlling the electrochemical reaction, i.e., the dissolving reaction, on the Cu film at a desired state. The Cu film formed on the wafer W can thus be polished accurately and reliably. Therefore, the polishing apparatus is capable of controlling the electrolytic polishing process in submicron levels, and hence of performing the electrolytic polishing process accurately and stably.

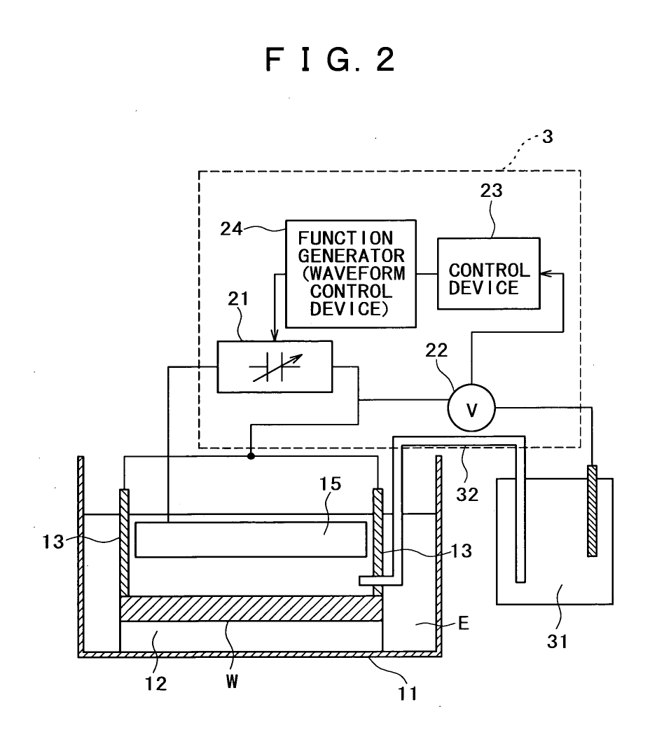

In the above embodiment, a calomel electrode is used as the reference electrode 14. However, the reference electrode 14 is not limited to such an electrode, but may be a known conventional electrode insofar as it can function as the reference electrode in the polishing apparatus. The reference electrode may comprise, for example, a silver/silver chloride electrode, a mercury/mercury oxide electrode. These reference electrodes may be commercially available stick-shaped electrodes. Alternatively, as shown in FIG. 2, a reference electrode 31 may be constructed using a salt bridge 32.

The present invention is also applicable to a polishing apparatus having a mechanism for rubbing the surface of a wafer with a polishing pad to polish the wafer based on a composite action of electrolytic polishing and wiping by the polishing pad, as well as the polishing apparatus having the above mechanism. A polishing apparatus having such a mechanism to which the present invention is applied will be described below.

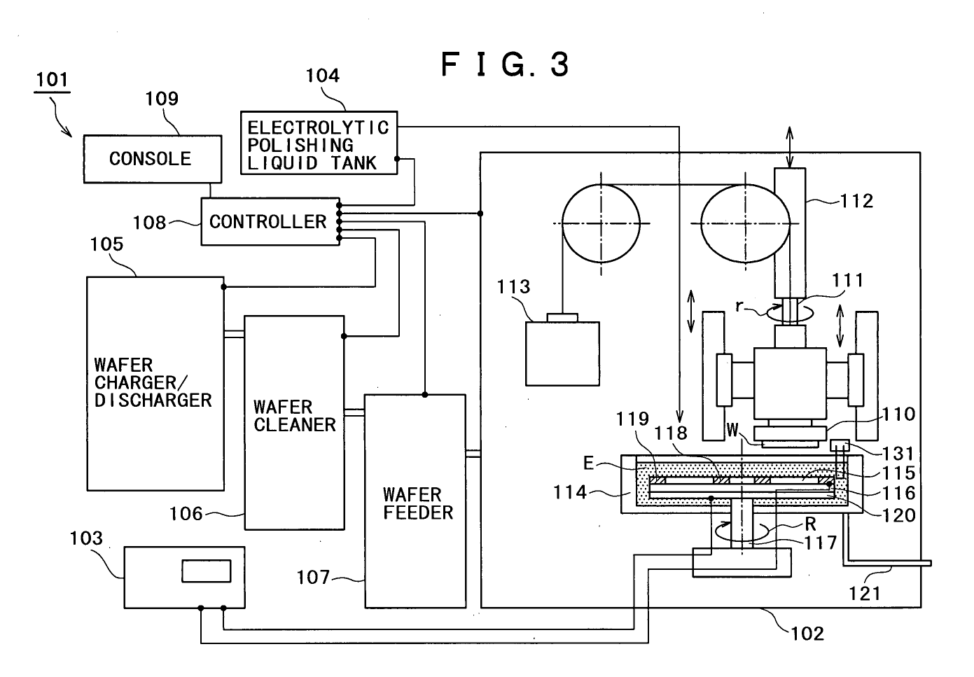

As shown in FIG. 3, a polishing apparatus 101 to which the present invention is applied comprises an apparatus assembly 102 for polishing a wafer W, a power supply 103 for supplying a predetermined electrolytic current to the apparatus assembly 102, an electrolytic liquid tank 104 for supplying an electrolytic liquid to an electrolytic tank in the apparatus assembly 102, a wafer charger/discharger 105 for introducing the wafer W into the polishing apparatus 101, a wafer cleaner 106 for cleaning the wafer W from the wafer charger/discharger 105, a wafer feeder 107 for feeding the wafer to and mounting the wafer W on and removing the wafer W from the apparatus assembly 102, a controller 108 for controlling the apparatus assembly 102, the electrolytic liquid tank 104, the wafer charger/discharger 105, the wafer cleaner 106, and the wafer feeder 107, and a console 109 for operating the controller 108.

The apparatus assembly 102 has a wafer chuck 110 for chucking the wafer W with the surface of the wafer W on which a Cu film is formed facing downwardly, a wafer rotating shaft 111 for rotating the wafer chuck 110 at a predetermined rotational speed in the direction indicated by the arrow r, and a wafer pressing means 112 for guiding the wafer chuck 110 to move vertically, i.e., in the direction of the Z-axis, and pressing the wafer chuck 110 downwardly under a predetermined pressure. The wafer pressing means 112 has a counterweight 113 for canceling the weights of the wafer chuck 110, the wafer rotating shaft 111, etc., and setting a pressure in the unit of 0.1 PSI (about 7 g/cm²), for example.

The apparatus assembly 102 has an electrolytic tank 114 disposed therein at a position facing the wafer chuck 110 for storing a predetermined amount of electrolytic liquid E therein. In the electrolytic tank 114, there is disposed a polishing pad 115 which is doughnut-shaped as viewed in plan for sliding contact with the surface of the wafer W while being immersed in the electrolytic liquid E. The polishing pad 115 is applied to a surface plate 116 and rotated at a predetermined rotational speed in the direction indicated by the arrow R by a pad rotating shaft 117 which supports the surface plate 116. The polishing pad 115 is made of foamed polyurethane, foamed polypropylene, polyvinyl acetal, or the like, and has a hardness (Young's modulus) ranging from 0.02 GPa to 0.10 GPa. The polishing pad 115 has slurry supply holes defined transversely therethrough for holding the electrolytic liquid E. Anodic energizing rings 118, 119 for sliding contact with edges of the wafer W and supplying a current to the wafer W as the anode are disposed respectively on inner and outer circumferential edges of the polishing pad 115 on the surface plate 116. The anodic energizing rings 118, 119 are made of an electrode material such as a carbon-based alloy, for example graphite, sintered Cu alloy, sintered silver alloy, or Pt, Cu. A cathode plate 120 is disposed below the polishing pad 115 in facing relation to the wafer W with the surface plate 116 interposed therebetween. The cathode plate 120 is supplied with a cathodic current through the electrolytic liquid E. The cathode plate 120 is of a disk shape and is made of an electrode material such as Cu, Pt. A waste liquid pipe 121 is connected to the electrolytic tank 114 for discharging only the electrolytic liquid E that has been used out of the apparatus assembly 102. In the electrolytic tank 114, a reference electrode 131 is disposed highly closely to the location where the wafer W is disposed in a polishing process. Since the wafer W rotates in the polishing process, it is necessary that the reference electrode 131 be disposed in a location out of interference with the rotating wafer W.

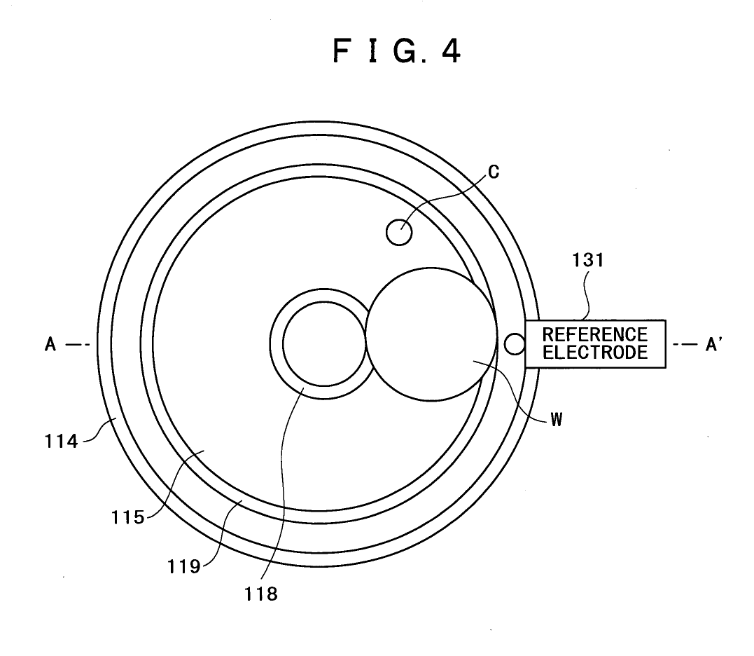

A process of polishing a Cu film 122 formed on the wafer W with the polishing apparatus 101 thus constructed will be described below with reference to FIGS. 4 through 7. First, the wafer W introduced from the wafer feeder 107 is chucked so as to face downwardly by the wafer chuck 110.

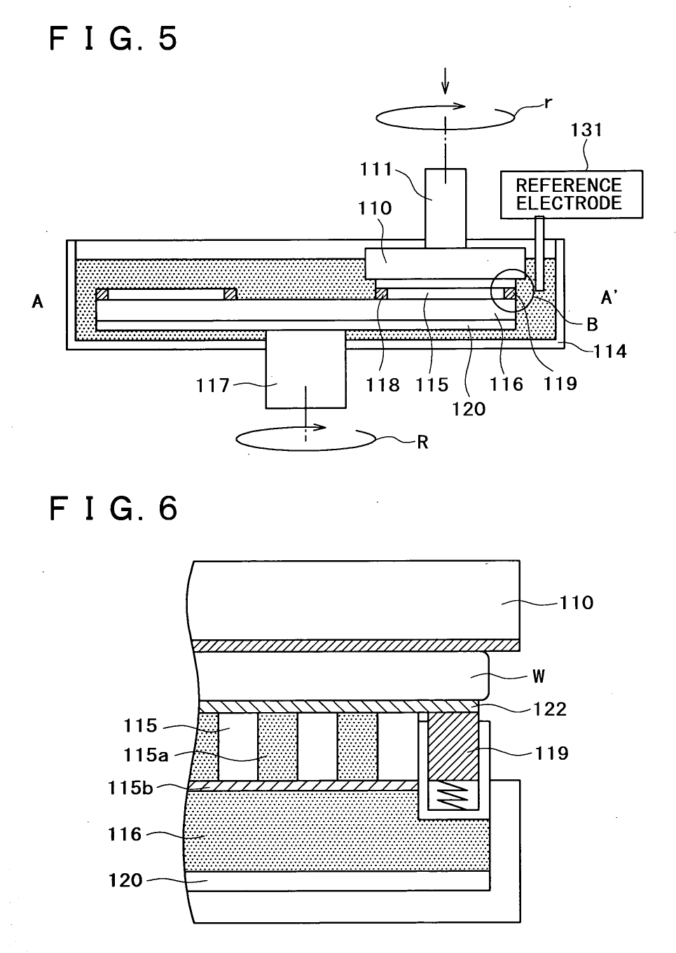

Then, as shown in FIG. 4 and FIG. 5 (which is a cross-sectional view taken along line A-A′ of FIG. 4), the wafer W is rotated at 10 rpm to 30 rpm, for example, in the direction indicated by the arrow r by the wafer rotating shaft 111, and pressed against the polishing pad 115 under a pressure ranging from 0.5 PSI to 1.5 PSI (35 g/cm² to 105 g/cm²) by the wafer pressing means 112. At the same time, the polishing pad 115 applied to the surface plate 116 is rotated at 60 rpm to 120 rpm in the direction indicated by the arrow R by the pad rotating shaft 117, and held in sliding contact with the surface of the wafer W with the electrolytic liquid E interposed therebetween.

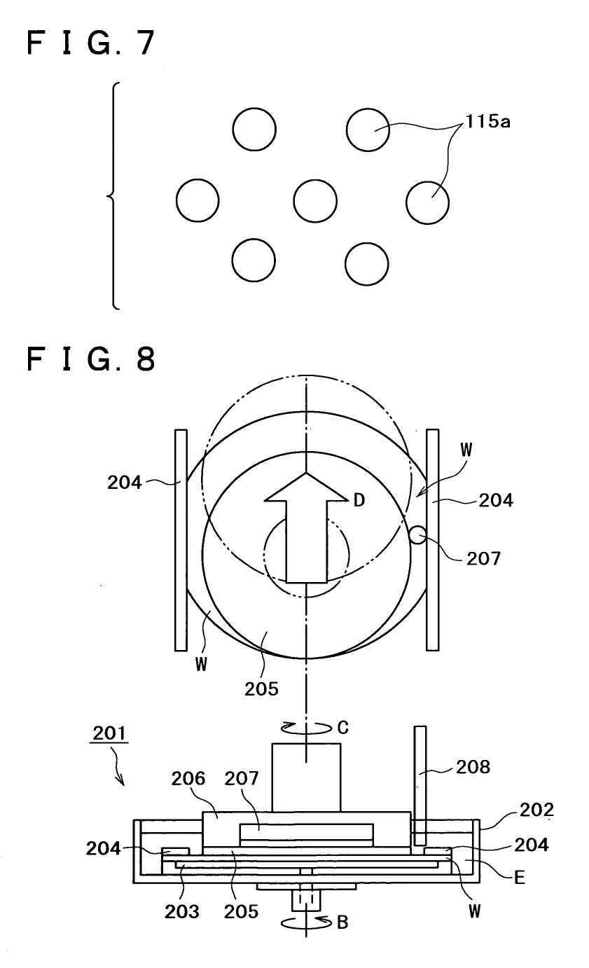

At this time, as shown in FIG. 4 and FIG. 6 (which is an enlarged cross-sectional view of an encircled area B in FIG. 5), a portion of the anodic energizing ring 118 disposed on the inner circumferential edge of the polishing pad 115 and a portion of the anodic energizing ring 119 disposed on the outer circumferential edge of the polishing pad 115 are always held in sliding contact with a portion of the outer circumferential edge of the Cu film 122 formed on the wafer W. As shown in FIG. 6 and FIG. 7 (which is an enlarged plan view of an encircled area C in FIG. 4), the polishing pad 115 has slurry supply holes 115a defined transversely therethrough, and the electrolytic liquid E is present from the surface of the wafer W (the Cu film 122) through a pad support screen 115b and the surface plate 116 to the cathode plate 120.

When a voltage ranging from 1 V to 3 V is applied from the power supply 103, an anodic current is supplied through the anodic energization rings 118, 119 to the Cu film 122, and an electrolytic current (at a current density ranging from 10 mA/cm² to 50 mA/cm²) required for electrolytic polishing flows through the slurry supply holes 115a in the confronting polishing pad 115 to the cathode plate 120. The surface of the Cu film 122 which is subjected to an electrolytic action as the anode undergoes anodic oxidization, with a Cu oxide film formed as its surface layer. The Cu oxide and a complex forming agent contained in the electrolytic liquid E react with each other, producing a Cu complex, which forms a alteration layer of a high electric resistance layer, an insoluble complex film, and a passive film on the surface of the Cu film 122.

At this time, the voltage between the Cu film 122 which is subjected to an electrolytic action as the anode and the reference electrode 131 is detected by a voltage detecting circuit (not shown). The detected result is analyzed by a control device (not shown), and the power supply 103 controls the voltage applied between the Cu film 122 and the reference electrode 131 so as to cause a desired electrochemical reaction on the Cu film 122 serving as the acting electrode based on the analyzed result. That is, the potential of the Cu film 122 is controlled at a predetermined potential for bringing about a desired electrochemical reaction from the start of the polishing process to the end of the polishing process. A function generator (not shown) controls a process of applying a power supply such as a direct current, a pulse, a triangle wave, a step wave, a ramp wave, etc. to apply a voltage having an optimum waveform.

Simultaneously with the anodic oxidization of the Cu film 122 based on the above electrolytic action, the surface of the Cu film 122 is wiped. Specifically, the polishing pad 115 is rubbed under pressure against the surface of the Cu film 122 to mechanically remove the alteration layer that is present on the surface layer of convex regions of the Cu film 122 which has surface irregularities, thereby exposing Cu in the base layer. On the other hand, the alteration layer that is present on concave regions of the Cu film 122 remains unremoved. The Cu surface exposed after the alteration layer on the convex regions has been removed is subjected again to an electrolytic action. The above cycle of electrolytic polishing and wiping is repeated to progressively planarize the Cu film 122 formed on the wafer W.

With the polishing apparatus 101, as described above, the potential of the Cu film 122 is controlled with respect to the potential of the reference electrode 131. Therefore, even when the resistance value of a portion of the circuit is changed by a change in the interfacial resistance or the electrode resistance of the counter electrode serving as the cathode or a change in the resistance value of the electrolytic liquid E during the polishing process, resulting in a change in the polishing environment, as with the polishing apparatus 1, the potential of the Cu film 122 serving as the anode can be controlled adequately, thus controlling the electrochemical reaction, i.e., the dissolving reaction, on the Cu film 122 at a desired state. It is made possible to control the valence at the time Cu is ionized in the interface between the Cu film 122 and the electrolytic liquid E, and dissolved ions and an additive for forming a complex can effectively be utilized, so that the planarizing ability can be increased. As a result, the Cu film 122 formed on the wafer W can be polished accurately and reliably. Therefore, the polishing apparatus is capable of controlling the electrolytic polishing process in submicron levels, and hence of performing the electrolytic polishing process accurately and stably.

Another polishing apparatus to which the present invention is applied which has a mechanism for rubbing the surface of a wafer with a polishing pad as with the polishing apparatus 101, for polishing the wafer based on a composite action of electrolytic polishing and wiping by the polishing pad, will be described below.

As shown in FIG. 8, a polishing apparatus 201 has a wafer chuck 203 for chucking a wafer W with a Cu film grown on a wafer substrate, the wafer chuck 203 being disposed in an electrolytic tank 202 storing an electrolytic liquid E therein. In the electrolytic tank 202, the wafer chuck 203 is rotated in the direction indicated by the arrow B by a drive motor (not shown). The wafer chuck 203 attracts the wafer W with a vacuum attracting means, for example. The wafer W attracted by the wafer chuck 203 is also rotated in the direction indicated by the arrow B by the wafer chuck 203.

As shown in FIG. 8, a pair of anode members 204 is disposed on diametrically opposite ends of a Cu film of the wafer W which is attracted by the wafer chuck 203. The anode members 204 are superposed on the ends of the Cu film across a predetermined width X, e.g., in an energization area of 5 mm. The superposed portions have an area of about 10% with respect to the entire circumference of the contact area, resulting in an ability to supply a sufficient electrolytic current to the Cu film.

A reference electrode 208 is fixedly disposed highly close to one of the anode members 204. A voltage detecting circuit, a function generator, and a power supply (not shown) are connected between the anode member 204 and the reference electrode 208.

As shown in FIG. 8, the polishing apparatus 201 has a polishing pad holding mechanism 206 holding a polishing pad 205 on a surface thereof facing the electrolytic tank 202. The polishing pad 205 is of a ring shape having a diameter smaller than the wafer W. The polishing pad 205 as it is held by the polishing pad holding mechanism 206 is actuated so as to be rotated in the direction indicated by the arrow C, and reciprocally moved in the direction indicated by the arrow D while sliding over the Cu film except in the positions where the anode members 204 are disposed, or specifically, between the anode members 204 on the diametrically opposite ends of the Cu film. A counter electrode 207 is disposed radially inwardly of the polishing pad holding mechanism 206 and between the polishing pad holding mechanism 206 and the polishing pad 205. In the polishing apparatus 201, the counter electrode 207 is disposed in confronting relation to the wafer W with a predetermined spacing therebetween in the electrolytic liquid E.

With the polishing apparatus 201, the anode members 204 supply a current to the Cu film that is formed as an anode on the wafer W to effect electrolytic polishing on the Cu film on the wafer W. At the same time as the electrolytic polishing, the wafer W is wiped by the polishing pad 205 which is rotated and moved in the direction indicated by the arrow D to slide over the Cu film. The wafer W is wiped by the polishing pad 205 under at most a pressure of 140 g/cm² which is a destructive pressure for the interlayer insulating film which is made of a material having a low dielectric constant, such as porous silica.

Since the Cu film is supplied with a current by the anode members 204 that are held in sliding contact with the wafer W under a low pressure, the current can be supplied in a stable uniform current density distribution. Therefore, the electrolytic polishing is performed at a good polishing rate under good polishing conditions. Portions of the Cu film that are supplied with the current by the anode members 204 are prevented from being dissolved prior to the end of the polishing process, and the electrolytic polishing can progress well until the end of the polishing process. With the polishing apparatus 201 described above, therefore, the Cu film is prevented from being left or excessively polished, thus suppressing the occurrence of short circuits and open areas of Cu wirings, and forming a smooth surface having stable wiring electric resistance.

As the polishing apparatus 201 simultaneously performs electrolytic polishing and wiping well with the anode members 204 disposed on the polished surface of the Cu film, it is not necessary to take into account contaminations that would occur between the polishing apparatus 201 and other apparatus and changes in the process of growing the Cu film on the wafer W, as when a Cu film is also grown on the reverse surface of the wafer W and a current is supplied from the reverse surface, and semiconductor devices can be manufactured according to a conventional semiconductor device fabrication process flow using conventional apparatus for growing Cu films and apparatus for cleaning polishing wafers.

Furthermore, the anode members 204 are pressed and the alteration layer is wiped under a pressure which is lower than the destructive pressure for a low-strength interlayer insulating film which is made of a material having a low dielectric constant. Therefore, the polishing apparatus 201 does not break the interlayer insulating film, e.g., does not peel off or produce crack in the interlayer insulating film, unlike the CMP process, and as a result can form good wirings.

With the polishing apparatus 201, the voltage between the Cu film which is subjected to the electrolytic action as the anode and the reference electrode 208 is detected by a voltage detecting circuit. The detected result is analyzed by a control device (not shown), and the power supply controls the voltage applied between the Cu film and the reference electrode 208 so as to cause a desired electrochemical reaction on the Cu film based on the analyzed result. That is, the potential of the Cu film is controlled at a predetermined potential for bringing about a desired electrochemical reaction from the start of the polishing process to the end of the polishing process. A function generator (not shown) controls a process of applying a power supply such as a direct current, a pulse, a triangle wave, a step wave, a ramp wave, etc. to apply a voltage having an optimum waveform.

Specifically, with the polishing apparatus 201, the potential of the Cu film is controlled with respect to the potential of the reference electrode 208. Therefore, even when the resistance value of a portion of the circuit is changed by a change in the interfacial resistance or the electrode resistance of the counter electrode serving as the cathode or a change in the resistance value of the electrolytic liquid E during the polishing process, resulting in a change in the polishing environment, as with the polishing apparatus 1, the potential of the Cu film serving as the anode can be controlled adequately, thus controlling the electrochemical reaction, i.e., the dissolving reaction, on the Cu film at a desired state. It is made possible to control the valence at the time Cu is ionized in the interface between the Cu film and the electrolytic liquid E, and dissolved ions and an additive for forming a complex can effectively be utilized, so that the planarizing ability can be increased. As a result, the Cu film formed on the wafer W can be polished accurately and reliably. Therefore, the polishing apparatus is capable of controlling the electrolytic polishing process in submicron levels, and hence of performing the electrolytic polishing process accurately and stably.

The electrolytic polishing process described above is applicable to a polishing process in the fabrication of semiconductor devices such as LSI circuits for removing excessive metal of a metal film grown to fill wiring grooves and planarizing the metal film to form metal wirings. A method of manufacturing a semiconductor device with the above electrolytic polishing process being carried out in the method will be described below. The method of manufacturing a semiconductor device forms a metal wiring of Cu according to the so-called damascene process. In the description which follows, the formation of a Cu wiring in a dual damascene structure in which wiring grooves and contact holes are simultaneously processed will be described. However, the present invention is also applicable to the formation of a Cu wiring in a single damascene structure in which only wiring grooves or only connection holes are formed.

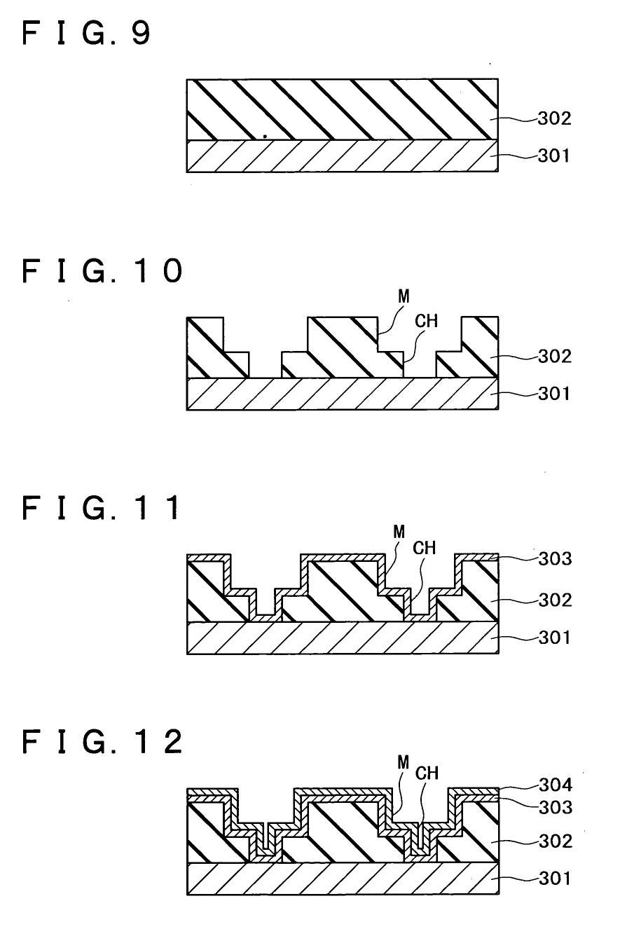

First, as shown in FIG. 9, an interlayer insulating film 302 made of a material having a low dielectric constant such as porous silica is formed on a wafer substrate 301 made of silicon or the like where devices (not shown) such as transistors are fabricated in advance. The interlayer insulating film 302 is formed by a low-pressure CVD (Chemical Vapor Deposition) process or the like.

Then, as shown in FIG. 10, contact holes CH and wiring grooves M leading to an impurity-diffused region (not shown) of the wafer substrate 301 are formed according to the known photolithography technology and the known etching technology.

Then, as shown in FIG. 11, a barrier metal film 303 is formed on the interlayer insulating film 302 in the contact holes CH and the wiring grooves M. The barrier metal film 303 is formed of a material such as Ta, Ti, W, Co, TaN, TiN, WN, CoW, COWP, by a PVD (Physical Vapor Deposition) process using a sputtering apparatus, a vacuum evaporation apparatus, or the like. The barrier metal film 303 is formed for the purpose of preventing Cu from being diffused into the interlayer insulating film.

After the barrier metal film 303 is formed, Cu is embedded in the contact holes CH and the wiring grooves M by any of various known techniques used heretofore, e.g., an electrolytic plating process, a CVD process, a sputtering and reflow process, a high-pressure reflow process, an electroless plating process. From the standpoints of a film growing rate and the purity and close contact of a metal material to be formed, it is preferable to embed Cu according to the electrolytic plating process. If Cu is embedded according to the electrolytic plating process, then, as shown in FIG. 12, a seed film 304 of the same material as the wiring forming material, i.e., Cu, is formed on the barrier metal film 303 by sputtering or the like. The seed film 304 is formed in order to promote the growth of a Cu grain when Cu is embedded in the wiring grooves M and the contact holes CH.

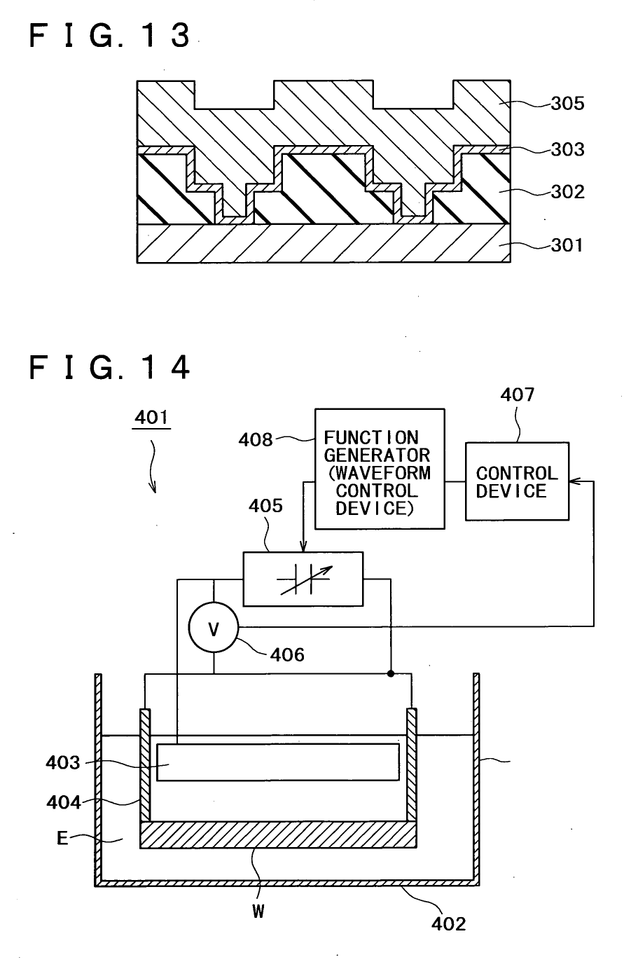

As shown in FIG. 13, Cu is embedded in the wiring grooves M and the contact holes CH according to any of the various processes described above by forming a Cu film 305 over the entire surface of the interlayer insulating film 302 including the wiring grooves M and the contact holes CH. The Cu film 305 has a film thickness equal to or greater than at least the depth of the wiring grooves M and the contact holes CH. Since the Cu film 305 is formed on interlayer insulating film 302 which has steps provided by the wiring grooves M and the contact holes CH, the Cu film 305 has steps depending on the pattern of the steps provided by the wiring grooves M and the contact holes CH. If Cu is embedded by the electrolytic plating process, then the seed film 304 formed on the barrier metal film 303 becomes integral with the Cu film 305.

The wafer substrate 301 with the Cu film 305 formed thereon as described above is then polished. In the polishing process, an electrolytic polishing process is carried out by simultaneously performing the electrolytic polishing using the electrolytic liquid and the wiping by the polishing pad as described above. Specifically, a current is supplied to the Cu 305 as the anode, and the Cu film 305 and the cathode plate are disposed in facing relation to each other in the electrolytic liquid, with an electrolytic current supplied for performing the electrolytic polishing process. At this time, the potential of the Cu film is appropriately controlled with reference to the reference electrode as described above.

At the same time, the polishing pad is pressed and slid against a alteration layer that has been produced on the surface of the Cu film 305 by the electrolytic polishing action under a pressure of at most 1.5 PSI (105 g/cm²), for example, which is a destructive pressure for a material having an ultra-low dielectric constant, such as porous silica, wiping away the alteration layer on convex regions of the Cu film 305. In the wiping process performed by the polishing pad, only the alteration layer on convex regions of the Cu film 305 is removed, and the alteration layer on concave regions remains unremoved. The electrolytic polishing process progresses to perform further anodic oxidization on the Cu film 305 in the base layer. Since the alteration layer is left on the concave regions at this time, the electrolytic polishing process does not progress in the concave regions, so that only the convex regions of the Cu film 305 are polished. The formation of the alteration layer according to the electrolytic polishing process and the removal of the alteration layer according to the wiping process are repeated to planarize the Cu film 305, forming Cu wirings 36 in the wiring grooves M and the contact holes H.

After the polishing process described above, the barrier metal film 303 is polished and cleaned, forming a cap film on the wafer substrate 301 with the Cu wirings formed thereon. The processes ranging from the formation of the interlayer insulating film 302 (shown in FIG. 9) to the formation of the cap film are repeated to produce multiple layers.

By performing the polishing process including electrolytic polishing and wiping in the process of manufacturing a semiconductor device, a current is supplied in a stable uniform current density distribution. The electrolytic polishing progresses at a good polishing rate under good polishing conditions until the end of the polishing process for thereby planarizing the Cu film and preventing the Cu film from being left or excessively polished. Thus, the occurrence of short circuits and open areas of Cu wirings is prevented, and a smooth surface having stable wiring electric resistance is formed.

The alteration layer is wiped under a pressure which is much lower than with the CMP process, or specifically a pressure which is lower than the destructive pressure for the interlayer insulating film 302 of low strength which is made of a material having a low dielectric constant, such as porous silica. Therefore, the interlayer insulating film 302 is prevented from being destroyed, e.g., from being peeled off or cracking.

According to the above process of manufacturing a semiconductor device, since the potential of the Cu film can appropriately be controlled with reference to the reference electrode, the Cu film formed on the wafer W can be polished accurately and reliably. Therefore, the surface of Cu wirings can highly be planarized without causing defects or the like after it is polished.

The polishing process in the process of manufacturing a semiconductor device has been described above. However, the present invention can be carried out in all other manufacturing processes including a process of polishing a metal film.

### INDUSTRIAL APPLICABILITY

In the polishing method according to the present invention, a substrate with a metal film formed thereon and a counter electrode are disposed in facing relation to each other in an electrolytic liquid, and a current is supplied to the metal film through the electrolytic liquid based on the potential of the metal film with respect to a reference electrode.

The polishing apparatus according to the present invention has, disposed in an electrolytic liquid, a substrate with a metal film formed thereon, a counter electrode disposed in facing relation to the substrate with a predetermined gap therebetween, and a reference electrode for providing a reference potential for the metal film, wherein a current is supplied to the metal film through the electrolytic liquid based on the potential of the metal film with respect to the reference electrode.

With the polishing method and the polishing apparatus according to the present invention, the potential of the metal film can appropriately be controlled with reference to the potential of the reference electrode. Therefore, the electrochemical reaction on the metal film can be controlled at a desired state, thereby controlling the polishing process in submicron levels, and hence performing the electrolytic polishing process accurately and stably.

The method of manufacturing a semiconductor device according to the present invention has the steps of forming an wiring groove in an insulating film on a substrate to form a metal wiring thereon, forming a metal film on the insulating film so as to fill the wiring groove, and polishing the metal film on the insulating film, wherein in the step of polishing the metal film, the substrate with the metal film formed thereon and a counter electrode are disposed in facing relation to each other in an electrolytic liquid, and a current is supplied to the metal film through the electrolytic liquid based on the potential of the metal film with respect to a reference electrode.

With the method of manufacturing a semiconductor device according to the present invention, since the above polishing method is carried out to planarize the surface of the wiring, the surface of the wiring can highly be planarized without causing defects or the like after it is polished.

1. A polishing method characterized by disposing a substrate with a metal film formed thereon and a counter electrode in facing relation to each other in an electrolytic liquid, and supplying a current to the metal film through the electrolytic liquid based on the potential of the metal film with respect to a reference electrode.

2. A polishing method according to claim 1, characterized in that said reference electrode comprises either one of a calomel electrode, a silver/silver chloride electrode, and a mercury/mercury oxide electrode.

3. A polishing method according to claim 1, characterized in that said reference electrode is disposed closely to said metal film.

4. A polishing method according to claim 1, characterized in that a voltage is applied to said metal film as an anode and said counter electrode as a cathode.

5. A polishing method according to claim 1, characterized in that said metal film comprises a copper film.

6. A polishing method according to claim 1, characterized in that while the current is being supplied to said metal film, said metal film has a surface polished by a polishing pad.

7. A polishing apparatus comprising:
a substrate with a metal film formed thereon;
a counter electrode disposed in facing relation to said substrate with a predetermined gap therebetween; and
a reference electrode for providing a reference potential for said metal film, said substrate, said counter electrode, and said reference electrode being disposed in an electrolytic liquid;
wherein a current is supplied to said metal film through said electrolytic liquid based on the potential of said metal film with respect to said reference electrode.

8. A polishing apparatus according to claim 7, characterized in that a voltage is applied to said metal film as an anode and said counter electrode as a cathode.

9. A polishing apparatus according to claim 8, comprising:
detecting means for detecting a voltage between said metal film and said reference electrode; and
control means for analyzing a detected result from said detecting means and controlling the applied voltage based on an analyzed result.

10. A polishing apparatus according to claim 8, comprising:
waveform control means for controlling the waveform of said voltage.

11. A polishing apparatus according to claim 7, characterized in that said reference electrode comprises either one of a calomel electrode, a silver/silver chloride electrode, and a mercury/mercury oxide electrode.

12. A polishing apparatus according to claim 7, characterized in that said reference electrode is disposed closely to said metal film.

13. A polishing apparatus according to claim 7, characterized in that said metal film comprises a copper film.

14. A polishing apparatus according to claim 7, comprising:
a polishing pad for sliding over said substrate to polish said metal film.

15. A method of manufacturing a semiconductor device, comprising the steps of
forming an wiring groove in an insulating film on a substrate to form a metal wiring thereon,
forming a metal film on said insulating film so as to fill said wiring groove, and
polishing said metal film on said insulating film,
wherein in the step of polishing said metal film, said substrate with said metal film formed thereon and a counter electrode are disposed in facing relation to each other in an electrolytic liquid, and a current is supplied to said metal film through said electrolytic liquid based on the potential of said metal film with respect to a reference electrode.

16. A method of manufacturing a semiconductor device according to claim 15, characterized in that said metal film is polished by polishing a surface of said metal film with a polishing pad while the current is being supplied to said metal film.
